(19) United States
(12) Patent Application Publication
(10) Pub. No.: US 2017/0104079 A1
(43) Pub. Date: Apr. 13, 2017

(54) VACUUM TUBE NONVOLATILE MEMORY AND THE METHOD FOR MAKING THE SAME

(71) Applicant: ZING SEMICONDUCTOR CORPORATION, Shanghai (CN)

(72) Inventors: DEYUAN XIAO, SHANGHAI (CN); RICHARD R. CHANG, Shanghai (CN)

(21) Appl. No.: 15/161,442

(22) Filed: May 23, 2016

(30) Foreign Application Priority Data
Oct. 12, 2015 (CN) 201510658550.7

(51) Int. Cl. H01L 29/423; H01L 29/792; H01L 29/66; H01L 21/311; H01L 21/28; H01L 21/3213; H01L 21/324; H01L 27/115; H01L 29/40

(52) U.S. Cl. CPC H01L 29/4234; H01L 27/11568; H01L 29/792; H01L 29/66833; H01L 29/408; H01L 21/28282; H01L 21/32134; H01L 21/324; H01L 21/31111

(57) ABSTRACT

The present invention provides a vacuum tube nonvolatile memory and the method of manufacturing it. The vacuum tube nonvolatile memory comprises oxide-nitride-oxide composite structure as gate dielectric layer, wherein the nitride layer can trap charges and provide better insulating block capability between the gate and vacuum channel. The present structure exhibits superior program and erase speed as well as the retention time. It also provides with excellent gate controllability and negligible gate leakage current due to adoption of the gate insulator.

### INCORPORATION BY REFERENCE

This application claims priority from China Patent Application No. 201510658550.7, filed on Oct. 12, 2015, the contents of which are hereby incorporated by reference in their entirety for all purposes.

### TECHNICAL FIELD

The present invention relates to a semiconductor manufacturing process, and particularly, relates to a vacuum tube nonvolatile memory and the method of manufacturing it.

### BACKGROUND

A vacuum tube is a type of electronic device that is usually sealed in a vacuum box to control the flow of electrons. In the early 20^{th} century, almost all of the electronic devices were made of vacuum tubes. However, the vacuum tubes have the drawbacks of high cost, short lifetime, big volume and low performance, They were largely replaced by solid state devices during the 1960s and 1970s. Only instruments that need high performance such as audio amplifiers, microwave stove, satellite transponders or even some of the fighter aircraft applications are still using vacuum tubes. Please refer to FIG. 1, it shows the circuit diagram of the conventional vacuum tube “Triode”, which includes a grid 1, plate 3, emitter 2 and filament 5. This additional control grid 1 modulates the current that flows from emitter 2 to plate 3.

Early electronics centered around the vacuum tube used to amplify, switch, or modulate electrical signals. It has been many decades since the vacuum tubes have been replaced by solid-state devices such as the MOSFET and BJT and diodes.

The vacuum tubes are still used in niche applications such as premier sound systems and high-power radio base stations. The transition from the vacuum tube to the solid-state device was not driven by the superiority of the semiconductor as a carrier transport medium but by the ease of fabrication, low cost, low-power consumption, lightness, long lifetime, and ideal form factor for integrated circuits.

The vacuum device is more robust than solid-state devices in extreme environments involving high temperature and exposure to various radiations.

The critical tradeoff is that the vacuum tubes yield higher frequency/power output but consume more energy than the MOSFET.

The vacuum is intrinsically superior to the solid as carrier transport medium since it allows ballistic transport while the carriers suffer from optical and acoustic phonon scattering in semiconductors. The velocity of electrons in vacuum is theoretically 3×1010 cm/s, but is limited to about 5×107 cm/s in semiconductors.

### SUMMARY

The present invention provides a vacuum tube nonvolatile memory and the method of manufacturing it. The present structure exhibits superior program and erase speed as well as the retention time. It also provides with excellent gate controllability and negligible gate leakage current due to adoption of the gate insulator.

In order to achieve the above advantages, an object of the present invention is to provide a vacuum tub nonvolatile memory. The vacuum tub nonvolatile memory comprises a substrate, a dielectric layer, a gate dielectric layer, a gate, a source and a drain, wherein the dielectric layer is on the substrate; the gate, source and drain are on the dielectric layer, the source and the drain located at one side of the gate respectively. The gate comprises a vacuum area to expose the sidewalls of the source and drain. The gate dielectric layer surrounds the vacuum area of the gate, and wherein the gate dielectric layer comprises oxide-nitride-oxide composite layers.

In one embodiment, wherein the source and the drain comprises convex shape towards the vacuum area.

In one embodiment, the vacuum tube nonvolatile memory further comprises sidewalls located on the side surfaces of the gate.

In one embodiment, wherein the dielectric layer comprises a trench, and the gate formed inside the trench.

An object of the present invention is also to provide a method of forming a vacuum tube nonvolatile memory, comprising the steps of:

providing a substrate;

forming a dielectric layer and a sacrificial layer on the substrate;

patterning the dielectric layer and the sacrificial layer to form an H shape bridge;

etching away the dielectric layer under the H shape bridge;

forming a gate dielectric layer on the sacrificial layer and the H shape bridge, wherein the gate dielectric layer comprises oxide-nitride-oxide composite layers;

forming a gate on the dielectric layer, wherein the gate surrounded the H shape bridge;

etching away the sacrificial layer and the H shape bridge to form a vacuum area inside said gate, wherein the gate dielectric layer in the vacuum area exposed;

forming sidewalls on the surface of the gate; and

forming a source and a drain areas at one side of the gate respectively.

In one embodiment, the method further comprises a step of annealing the H shape bridge to make it a rounded shape after forming the H shape bridge.

In one embodiment, the annealing is operated at a He, H₂ Ar or N₂ atmosphere.

In one embodiment, the annealing is operated at a temperature range of 600˜1000° C.

In one embodiment, a pressure of the vacuum area is in a range of 0.1˜50 torr.

In one embodiment, wherein etching away the sacrificial layer and the H shape bridge comprises the steps of:

etching away the gate dielectric layer on said sacrificial layer to expose the sacrificial layer;

etching away exposed sacrificial layer to expose sidewalls of the H shape bridge;

selectively wet etching the H shape bridge inside the gate.

In one embodiment, wherein etching away exposed sacrificial layer is performed by dry etching.

In one embodiment, the method further comprises a step of oxidizing or nitrodizing the gate with O₂, N₂O or NH₃ plasma or ALD deposition of Al₂O₃ or AlN on the gate after etching the H shape bridge.

In one embodiment, the source and drain are a material selected from the group consisting of Zr, V, Nb, Ta, Cr, Mo, W, Fe, Co, Pd, Cu, Al, Ga, In, Ti, TiN, TaN, diamond and the combination thereof.

In one embodiment, the sacrificial layer is a material selected from the group consisting of Al, Ge, Si, Cr, Mo, W, Fe, Co, Cu, Ga, In, and Ti.

In one embodiment, the oxide-nitride-oxide composite layers comprise silicon dioxide-silicon nitride-silicon dioxide.

Compared with conventional technology, the present invention has advantages of superior program and erase speed as well as the retention time. It also provides with excellent gate controllability and negligible gate leakage current due to adoption of the gate insulator. Also, by using oxide-nitride-oxide composite gate dielectric layers with nitride layer as charge-trap layer, it provides better insulating block capability between the gate and vacuum channel.

### BRIEF DESCRIPTION OF THE DRAWINGS

Exemplary embodiments will be more readily understood from the following detailed description when read in conjunction with the appended drawing, in which:

FIG. 1 is a schematic diagram showing a conventional vacuum tube structure;

FIG. 2 illustrates an example cross-sectional view of a vacuum tube nonvolatile memory according to an example embodiment of the present invention;

FIG. 3 is a cross-sectional view along the A-A′ direction according to one embodiment of the present invention;

FIG. 4 is a cross-sectional view along the B-B′ direction according to one embodiment of the present invention;

FIG. 5 is a flow chart of a fabrication method of a vacuum tube nonvolatile memory according to one embodiment of the present invention; and

FIGS. 6-15 are cross-sectional views showing process stages of manufacturing a vacuum tube nonvolatile memory according to one embodiment of the present invention.

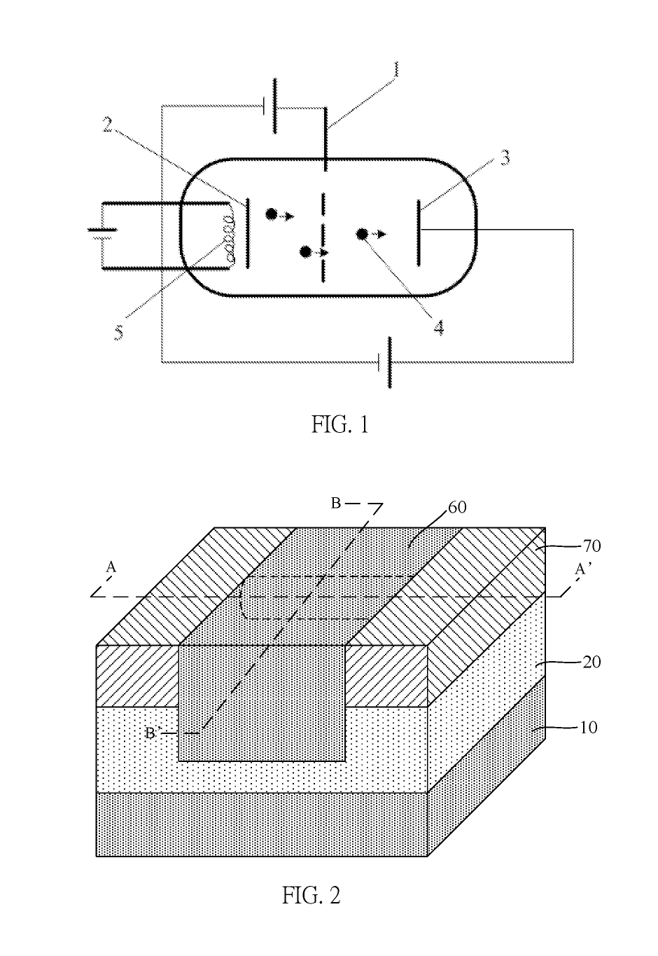

### DETAILED DESCRIPTION

The following detailed description in conjunction with the drawings of a vacuum tube nonvolatile memory and fabrication method thereof of the present invention represents the preferred embodiments. It should be understood that the skilled in the art can modify the present invention described herein to achieve advantageous effect of the present invention. Therefore, the following description should be understood as well known for the skilled in the art, but should not be considered as a limitation to the present invention.

For purpose of clarity, not all features of an actual embodiment are described. It may not describe the well-known functions as well as structures in detail to avoid confusion caused by unnecessary details. It should be considered that, in the developments of any actual embodiment, a large number of practice details must be made to achieve the specific goals of the developer, for example, according to the requirements or the constraints of the system or the commercials, one embodiment is changed to another. In addition, it should be considered that such a development effort might be complex and time-consuming, but for a person having ordinary skills in the art is merely routine work.

In the following paragraphs, the accompanying drawings are referred to describe the present invention more specifically by way of example. The advantages and the features of the present invention are more apparent according to the following description and claims. It should be noted that the drawings are in a simplified form with non-precise ratio for the purpose of assistance to conveniently and clearly explain an embodiment of the present invention.

Reference is now made to FIGS. 2-4, which illustrate an example cross-sectional view of a vacuum tube nonvolatile memory according to an example embodiment of the present invention. The vacuum tube nonvolatile memory includes a substrate 10, a dielectric layer 20, a gate dielectric layer, a gate 50, and source/drain 70. As shown in the Figures, the dielectric layer 20 is on the substrate 10, the source/drain region 70 is on the dielectric layer 20, and the source/drain region 70 located on each side of the gate 50 respectively. The gate 50 comprises a vacuum region 52 to expose the sidewalls of the source/drain region 70. A gate dielectric layer is formed surrounding the vacuum area 52, and the gate dielectric layer comprises oxide-nitride-oxide composite layers 41/42/43 in this embodiment.

In one embodiment, the vacuum field effect transistor nonvolatile memory further comprises sidewalls 60 located on the side surfaces of the gate 50. The source/drain region 70 comprises convex shape towards the vacuum region 52, in particular, the source/drain region 70 has curve convex shape towards the vacuum region 52. The dielectric layer 20 comprises a trench, and the gate 50 is formed inside the trench.

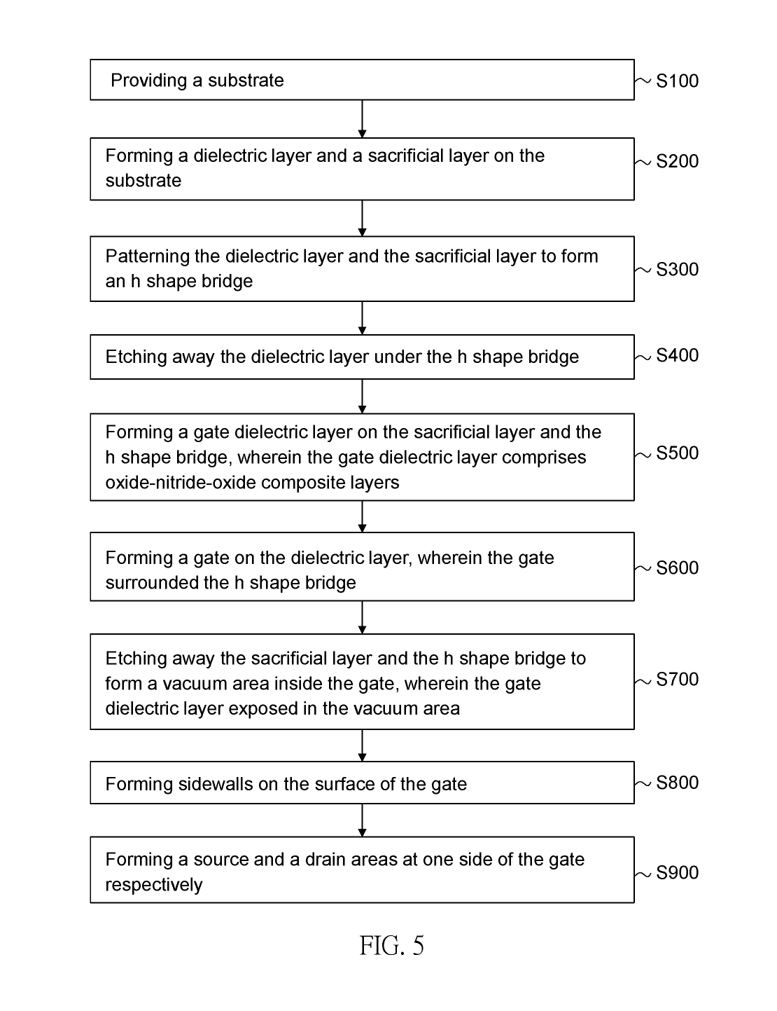

Please refer to FIG. 5, it illustrates a flow chart of manufacturing a vacuum tube nonvolatile memory according to an example embodiment of the present invention. The method includes the steps of:

S100: providing a substrate;

S200: forming a dielectric layer and a sacrificial layer on the substrate;

S300: patterning the dielectric layer and the sacrificial layer to form an H shape bridge;

S400: etching away the dielectric layer under the H shape bridge;

S500: forming a gate dielectric layer on the sacrificial layer and the H shape bridge, wherein the gate dielectric layer comprises oxide-nitride-oxide composite layers;

S600: forming a gate on the dielectric layer, wherein the gate surrounded the H shape bridge;

S700: etching away the sacrificial layer and the H shape bridge to form a vacuum area inside the gate, wherein the gate dielectric layer in the vacuum area exposed;

S800: forming sidewalls on the surface of the gate; and

S900: forming a source and a drain area on each side of the gate respectively.

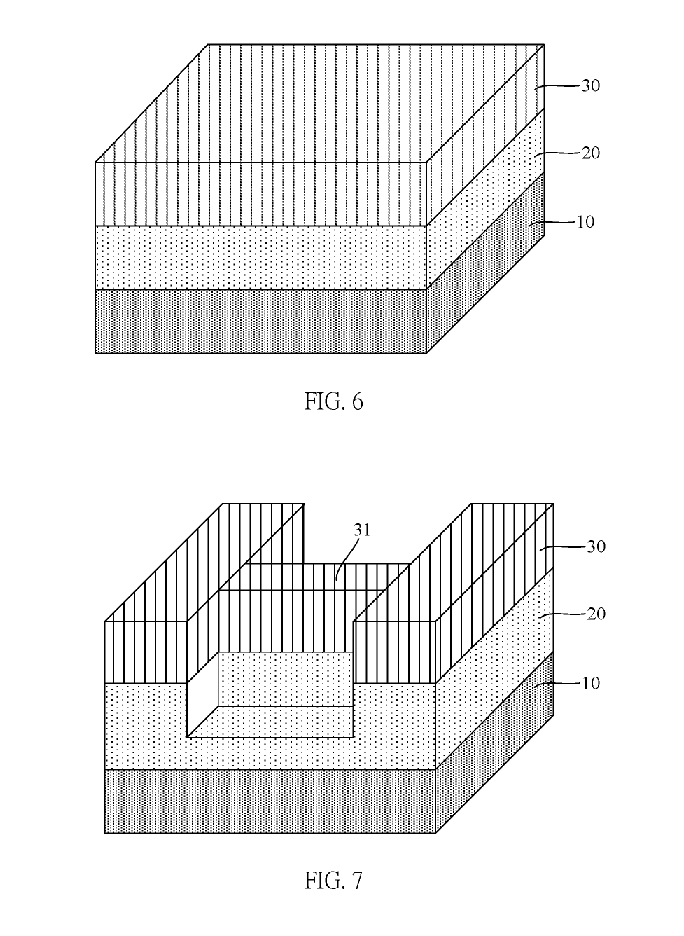

In particular, please refer to the following FIGS. 6-15 for the manufacturing process details. Now, refer to FIG. 6, it illustrates the cross-sectional view after the first step of manufacturing the vacuum tube nonvolatile memory according to an example embodiment of the present invention. A dielectric layer 20 and a sacrificial layer 30 are sequentially formed on a substrate 10. In one embodiment, the substrate 10. can be a silicon wafer, a silicon on insulator (SOI) substrate or the like. The dielectric layer 20 is silicon dioxide, and the sacrificial layer 30 can be aluminum (Al), poly Si, Ge, Cr, Mo, W, Fe, Co, Cu, Ga, In, Ti, preferably is Al.

Next, refer to FIG. 7, it illustrates the cross-sectional view after the second step of manufacturing the vacuum tube nonvolatile memory according to an example embodiment of the present invention. The dielectric layer 20 and sacrificial layer 30 are patterned to form an H shape bridge. The H shape bridge can be referred as fin shape structure as well. The patterning can be achieved by conventional silicon patterning technology such as photolithography.

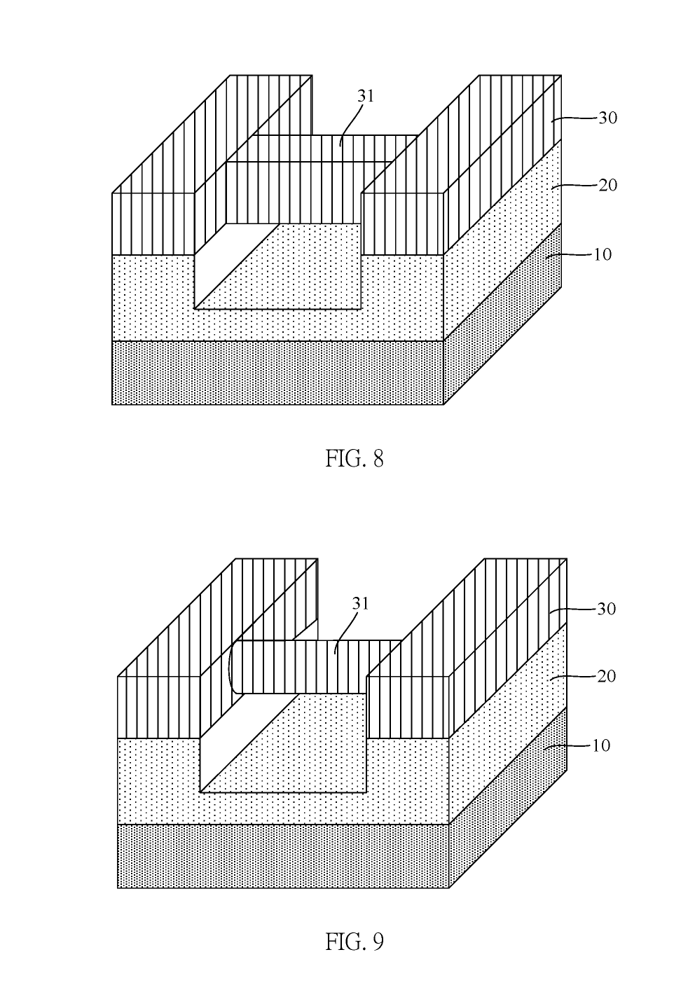

Next, refer to FIG. 8, it illustrates the cross-sectional view after the third step of manufacturing the vacuum tube nonvolatile memory according to an example embodiment of the present invention. The dielectric layer 20 under the H shape bridge 31 etched away to let the H shape bridge 31 overhanging above the remaining dielectric layer 20.

Next, refer to FIG. 9, it illustrates the cross-sectional view after the fourth step of manufacturing the vacuum tube nonvolatile memory according to an example embodiment of the present invention. The H shape bridge 31 annealed to turn the cuboid shaped bridge 31 into a cylindrical nanowire as shown in the Figure. The step can improve the reliability of the vacuum tube nonvolatile memory since it can reduce the stress of the H shape bridge 31. In one embodiment, the anneal process is performed in the environment such as He, N2, Ar or H₂ in the temperature range of 600˜1000° C., preferably in 800° C.

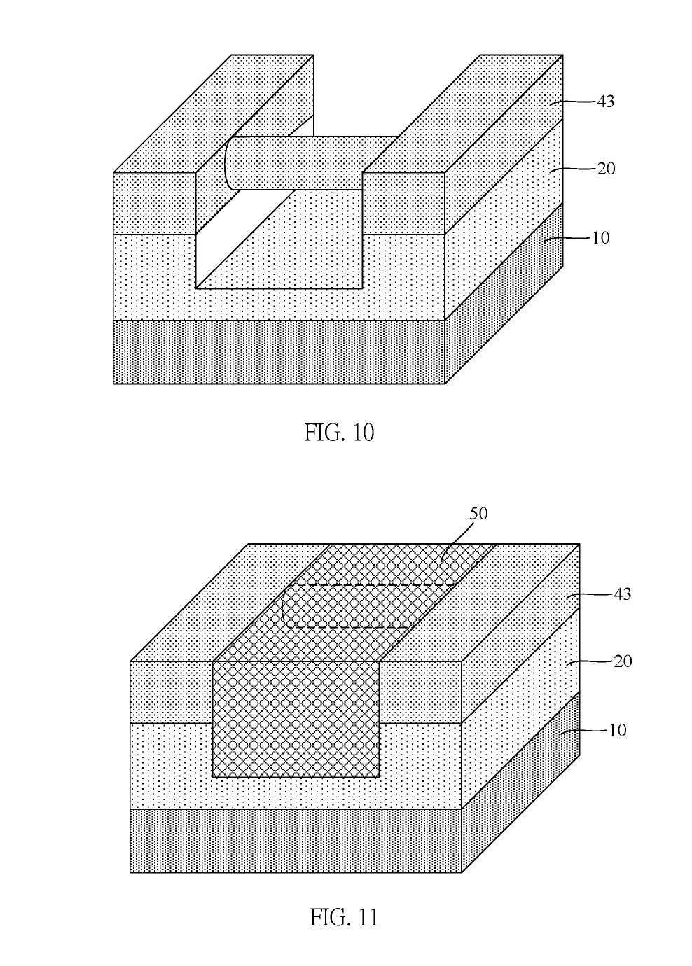

Next, refer to FIG. 10, it illustrates the cross-sectional view after the fifth step of manufacturing the vacuum tube nonvolatile memory according to an example embodiment of the present invention. A gate dielectric layer is formed on the H shape bridge 31 and sacrificial layer 30. In one embodiment, the gate dielectric layer is oxide-nitride-oxide (ONO) composite layers 41/42/43 deposited by CVD, PVD, ALD techniques.

Next, refer to FIG. 11, it illustrates the cross-sectional view after the sixth step of manufacturing the vacuum tube nonvolatile memory according to an example embodiment of the present invention. A gate layer 50 is formed on the dielectric layer 20, the gate layer surrounded the H shape bridge 31. In one embodiment, the gate layer is a metal gate layer deposited by CVD, MOCVD, PVD techniques. The gate patterning can be achieved by conventional silicon patterning technology such as photolithography and dry etching.

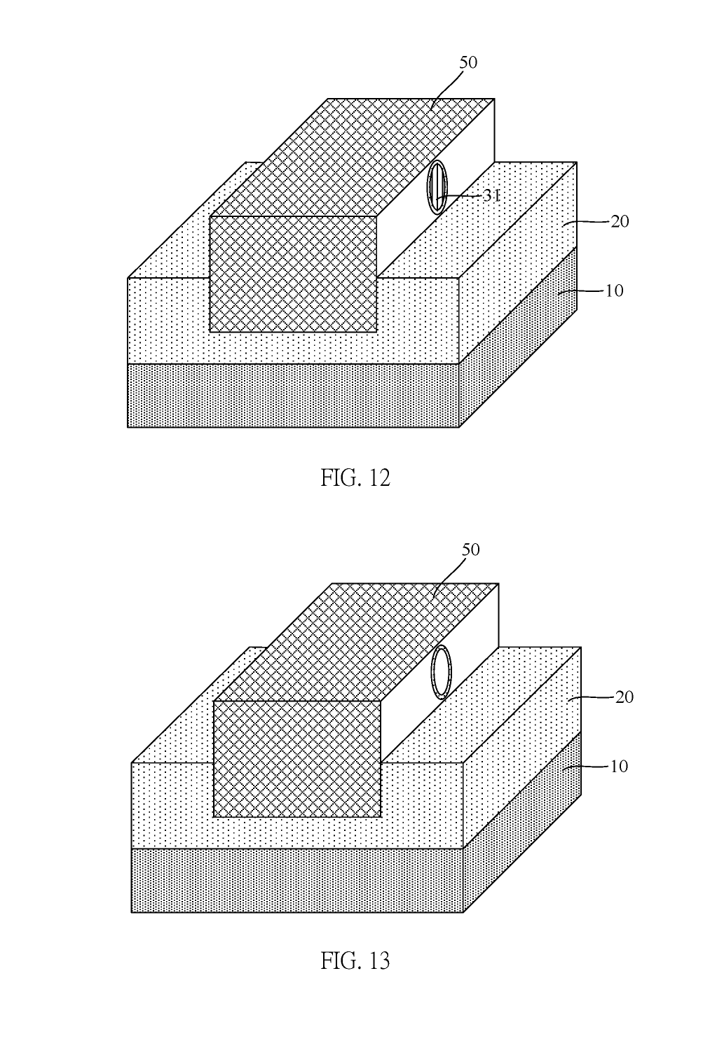

Next, refer to FIG. 12, it illustrates the cross-sectional view after the seventh step of manufacturing the vacuum tube nonvolatile memory according to an example embodiment of the present invention. The sacrificial layer 30 and the H shape bridge 31 are removed. In one embodiment, the gate dielectric layer on the sacrificial layer 30 are etching away first, followed by etching away the sacrificial layer 30 to expose the dielectric layer 20 on both sides of the gate 50, and finally the H shape bridge 31 is removed as well to form a vacuum area inside said gate 50 as shown in FIG. 13. In one embodiment, the sacrificial layer etching can be achieved by conventional silicon patterning technology such as photolithography and dry etching, while the H shape bridge is removed by selectively wet etching.

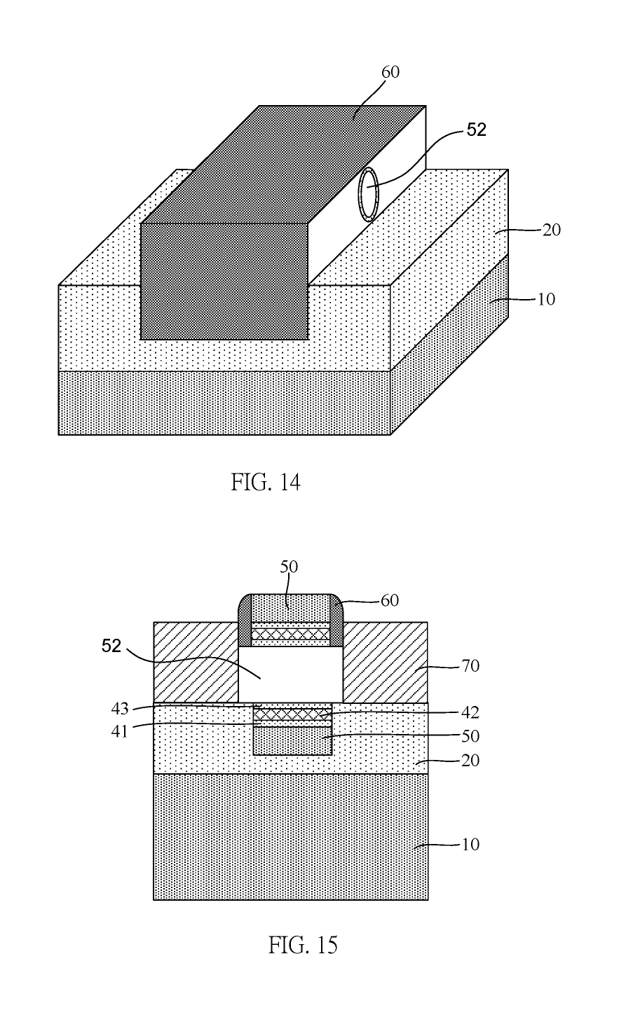

Next, refer to FIG. 14, it illustrates the cross-sectional view after the ninth step of manufacturing the vacuum tube nonvolatile memory according to an example embodiment of the present invention. The gate 50 performed thermal or ALD processes to form sidewalls 60 on the surface of the gate. In one embodiment, the thermal process is an oxidation process in the O₂ environment to form Al₂O₃ as sidewalls on the gate surface. In another embodiment, the thermal process is a nitridation process in the N₂O, or NH₃ environment to form AlN as sidewalls on the gate surface.

Next, a source and a drain areas 70 are formed on each side of the gate 50 respectively as previously shown in FIG. 2. In one embodiment, the source and drain 70 is metal, and the metal materials include Zr, V, Nb, Ta, Cr, Mo, W, Fe, Co, Pd, Cu, Al, Ga, In, Ti, TiN, TaN, diamond or the combination of these materials. In one embodiment, the gate layer is a metal gate layer s deposited by CVD, MOCVD, PVD techniques. The source and drain areas 70 can be deposited by CVD, or PVD techniques. The vacuum area 52 is formed by sealing the gate 50 and source and drain areas 70. In one embodiment, the pressure in the vacuum area 52 is in the range of 0.1 torr˜50 torr.

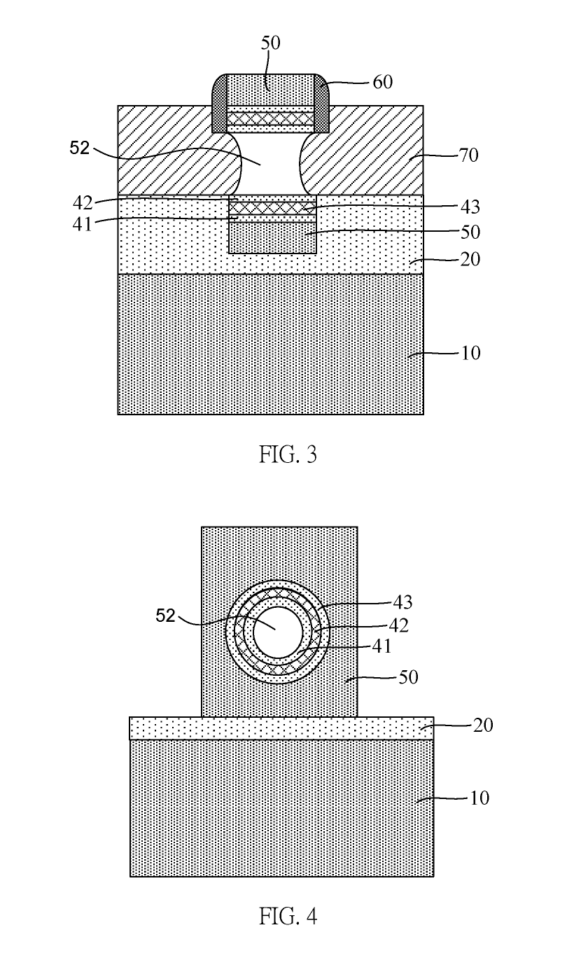

Finally, refer to FIG. 15, it illustrates the cross-sectional view after the tenth step of manufacturing the vacuum tube nonvolatile memory according to an example embodiment of the present invention. The source and drain areas 70 performed thermal treatment processes a H₂ or N₂ environment to form a convex shape towards the vacuum region 52 as shown in FIG. 3 to enhance the performance of the vacuum tube nonvolatile memory. In one embodiment, the thermal treatment process is performed in the temperature range of 600˜1000° C.

According to the description above, the present invention disclosed a vacuum tube nonvolatile memory and the method of manufacturing it. The field effect transistor nonvolatile memory is a Metal-ONO-Vacuum Field Effect Transistor Charge Trap Nonvolatile Memory using standard silicon semiconductor processing. The source and drain were separated and replaced by low electron affinity conducting material, with the curvature of the tip controlled by the thermal reflow of the source metal material. An ONO gate dielectric with a nitride charge-trap layer to provide a blocking insulating between the gate electrode and the vacuum channel. The present structure exhibits superior program and erase speed as well as the retention time. It also provides with excellent gate controllability and negligible gate leakage current due to adoption of the gate insulator.

While various embodiments in accordance with the disclosed principles been described above, it should be understood that they are presented by way of example only, and are not limiting. Thus, the breadth and scope of exemplary embodiment(s) should not be limited by any of the above-described embodiments, but should be defined only in accordance with the claims and their equivalents issuing from this disclosure. Furthermore, the above advantages and features are provided in described embodiments, but shall not limit the application of such issued claims to processes and structures accomplishing any or all of the above advantages.

Additionally, the section headings herein are provided for consistency with the suggestions under 37 C.F.R. 1.77 or otherwise to provide organizational cues. These headings shall not limit or characterize the invention(s) set out in any claims that may issue from this disclosure. Specifically, a description of a technology in the “Background” is not to be construed as an admission that technology is prior art to any invention(s) in this disclosure. Furthermore, any reference in this disclosure to “invention” in the singular should not be used to argue that there is only a single point of novelty in this disclosure. Multiple inventions may be set forth according to the limitations of the multiple claims issuing from this disclosure, and such claims accordingly define the invention(s), and their equivalents, that are protected thereby. In all instances, the scope of such claims shall be considered on their own merits in light of this disclosure, but should not be constrained by the headings herein.

1. A vacuum tube nonvolatile memory, comprising:
a substrate;
a dielectric layer on said substrate;
a gate, a source and a drain on said dielectric layer, said source and said drain located at one side of said gate respectively;
wherein said gate comprises a vacuum area to expose the sidewalls of said source and said drain;
wherein a gate dielectric layer surrounds said vacuum area of said gate; and
wherein said gate dielectric layer comprises oxide-nitride-oxide composite layers.

2. The vacuum tube nonvolatile memory according to claim 1, wherein said source and said drain comprises convex shape towards said vacuum area.

3. The vacuum tube nonvolatile memory according to claim 1, further comprising sidewalls located on the side surfaces of said gate.

4. The vacuum tube nonvolatile memory according to claim 1, wherein said dielectric layer comprises a trench, and said gate formed inside said trench.

5. A method of forming a vacuum tube nonvolatile memory, comprising the steps of:
providing a substrate;
forming a dielectric layer and a sacrificial layer on said substrate;
patterning said dielectric layer and said sacrificial layer to form an H shape bridge;
etching away said dielectric layer under said H shape bridge;
forming a gate dielectric layer on said sacrificial layer and said H shape bridge, wherein said gate dielectric layer comprises oxide-nitride-oxide composite layers;
forming a gate on said dielectric layer, wherein said gate surrounded said H shape bridge;
etching away said sacrificial layer and said H shape bridge to form a vacuum area inside said gate, wherein said gate dielectric layer exposed in said vacuum area;
forming sidewalls on the surface of said gate; and
forming a source and a drain areas at one side of said gate respectively.

6. The method of claim 5, further comprising a step of annealing said H shape bridge to make it a rounded shape after forming said H shape bridge.

7. The method of claim 6, wherein said annealing is operated at a He, H₂ Ar or N₂ atmosphere.

8. The method of claim 6, wherein said annealing is operated at a temperature range of 600˜1000° C.

9. The method of claim 5, wherein a pressure of said vacuum area is in a range of 0.1˜50 torr.

10. The method of claim 5, wherein said etching away said sacrificial layer and said H shape bridge comprises the steps of:
etching away said gate dielectric layer on said sacrificial layer to expose said sacrificial layer;
etching away exposed sacrificial layer to expose sidewalls of said H shape bridge;
selectively wet etching said H shape bridge inside said gate.

11. The method of claim 10, wherein etching away exposed sacrificial layer is performed by dry etching.

12. The method of claim 5, further comprising a step of oxidizing or nitrodizing said gate with O₂, N₂O or NH₃ plasma or ALD deposition of Al₂O₃ or AN on said gate after etching said H shape bridge.

13. The method of claim 5, wherein said source and said drain are a material selected from the group consisting of Zr, V, Nb, Ta, Cr, Mo, W, Fe, Co, Pd, Cu, Al, Ga, In, Ti, TiN, TaN, diamond and the combination thereof.

14. The method of claim 5, further comprising a step of annealing said source and said drain.

15. The method of claim 14, wherein said annealing is operated at a H₂ or N₂ atmosphere.

16. The method of claim 15, wherein said annealing is operated at a temperature range of 600˜1000° C.

17. The method of claim 5, wherein said sacrificial layer is a material selected from the group consisting of Al, Ge, Si, Cr, Mo, W, Fe, Co, Cu, Ga, In, and Ti.

18. The method of claim 5, wherein said oxide-nitride-oxide composite layers comprises silicon dioxide-silicon nitride-silicon dioxide.
